(19) United States
(12) Patent Application Publication
(10) Pub. No.: US 2011/0006331 A1
(43) Pub. Date: Jan. 13, 2011

(54) LIGHT-EMITTING DEVICE WITH A SEMI-REMOTE PHOSPHOR COATING

(76) Inventor: Alexander Shaikevitch, Livermore, CA (US)

Correspondence Address: BridgeLux, Inc., 101 PORTOLA AVENUE, LIVERMORE, CA, 94551, US

(21) Appl. No.: 12/886,349

(22) Filed: Sep. 20, 2010

(51) Int. Cl. H01L 33/60

(52) U.S. Cl. 257/98; 438/29; 257/E33.045

(57) ABSTRACT

A complex lens and a light-emitting device comprising a complex lens are disclosed. At least one semiconductor die is disposed on a substrate. The complex lens is created by forming a first lens comprising a clear transparent material directly on a surface of each of at least one die, and by forming an outer lens comprising a clear transparent material filled uniformly with phosphor, directly encapsulating the substrate and the at least one die with the formed first lens. The outer lens is in contact with the substrate either directly or through an intervening reflective layer of the light-emitting device.

### BACKGROUND

1. Field

The present disclosure relates to a light-emitting device, and more particularly, to a method and an apparatus for light-emitting device arrays.

2. Description of Related Technology

A person skilled in the art will appreciate that the concepts disclosed herein are applicable to packages for semiconductor-based light-emitting device, namely a light-emitting diode (LED) device.

LEDs have been used for many years in various light requiring applications, e.g., signaling states for devices, i.e., light on or off, opto-couplers, displays, replacement of bulbs in flashlights, and other applications known in the art. Consequently, LEDs emitting both spectral colors and white light have been developed. There are two primary approaches to producing light with desired properties using LEDs. One is to use individual LED dice that emit the three primary colors—red, green, and blue, and then mix the colors to produce light with the desired properties. The other approach is to use a phosphor material to convert monochromatic light from a blue or ultra-violet color emitting LED die or dice to a light with the desired properties, much in the same way a fluorescent light bulb works. For the purposes of this disclosure a die has its common meaning of a light-emitting semiconductor chip comprising a p-n junction.

Due to LEDs' advantages, i.e., light weight, low energy consumption, good electrical power to light conversion efficiency, and the like, an increased interest has been recently focused on use of LEDs even for high light intensity application, e.g., replacement of conventional, i.e., incandescent and fluorescent light sources, traffic signals, signage, and other high light intensity applications known to a person skilled in the art. It is customary for the technical literature to use the term “high power LED” to imply high light intensity LED; consequently, such terminology is adopted in this disclosure, unless noted otherwise. To increase intensity of the light emitted by the light-emitting device, often more than one light-emitting die is arranged in a package; such a light-emitting device being termed a light-emitting device array. For the purposes of this disclosure, a package is a collection of components comprising the light-emitting device including but not being limited to: a substrate, a die or dice (if an array), phosphors, encapsulant, bonding material(s), light collecting means, and the like. A person skilled in the art will appreciate that some of the components are optional.

There are three main approaches for coating LED die with phosphor(s): freely dispersed coating, conformal coating, and remote coating. Freely dispersed coating is the oldest method that was developed for white light-emitting LEDs. FIG. 1 depicts a conceptual cross-section of an exemplary light-emitting device 100, on which phosphor was dispersed in accordance with this method. A die or a plurality of dice 104 (three dice shown) is disposed on a substrate 102 in accordance with design goal for the light-emitting device 100. To limit the dispersion area, i.e., the designated area to be coated with phosphor 106, a fence 108 is disposed on the substrate 102. Phosphor 106 is then dispersed without any mold restriction into the dispersion area, where the phosphor silicone 106 flows freely until a surface balance is achieved. As a result of this process, the phosphor layer 106 is normally convex and the central zone is thicker than that of the marginal zone. As a consequence of the uneven thickness, the characteristics of light emitted from the central zone tend to be of different characteristics (“warmer”) than the characteristics of light emitted from the marginal zone. An advantage of this method is that an average thickness of the phosphor layer can be easily controlled by volume of the phosphor and size of the dispersion area. No special technique is required thereby reducing manufacturing time and cost.

FIG. 2 depicts a conceptual cross-section of an exemplary light-emitting device 200, on which phosphor was dispersed in accordance with the process of conformal coating. A die or a plurality of dice 204 (three dice shown) is disposed on a substrate 202 in accordance with design goal for the light-emitting device 200. A phosphor layer 206 is produced by electrophoretic deposition, stacking phosphor particles to obtain highly concentrated uniform layer on the die or a plurality of dice 204 surface as well as on the substrate 202. The uniformity of the phosphor layer 206 on the die or a plurality of dice 204 surface results in light with uniform characteristics. The thickness of the phosphor film is controlled by a magnitude of voltage and a deposition time. A person skilled in the art will appreciate that other approaches for conformal coating, e.g., gravitational settling, solvent evaporation, and wafer-level coating can be employed.

The two above-described methods deposit the phosphor layer directly on the die or the plurality of dice surface, thus minimizing LED size. However, experimental results confirmed that due to the close proximity between the die or the plurality of dice surface and the phosphor layer, approximately 50-60% light emitted by the die or the plurality of dice is back-scattered by the phosphor layer. This back scattered light may be absorbed by the die or the plurality of dice; consequently, decreasing the efficiency of light-extraction from the light-emitting device.

The absorption of light by the die or the plurality of dice due to back-scattering may be mitigated by moving the phosphor layer to remote location, i.e., location away from the die or the plurality of dice surface. A conceptual cross-section of such exemplary light-emitting device 300 is depicted in FIG. 3a. A die or a plurality of dice 304 (three dice shown) is disposed on a substrate 302 in accordance with design goal for the light-emitting device 300. To improve light-extraction by reflecting photons emitted from the dice 304 into an undesirable direction, a reflector 306 is disposed on the substrate 302. To acquire a desired reflectivity, the surface of the substrate 302 and/or the reflector 306 exposed to the light emitted from the plurality of dice 304 may be treated, e.g., by polishing, buffing, or any other process known to a person skilled in the art. Alternatively, the desired reflectivity is achieved by applying a layer of a material with high reflectivity, such as Ag, Pt, and any like materials known to a person skilled in the art onto such surfaces (not shown in FIG. 3a). Reflectivity is characterized by a ratio of reflected to incident light.

An encapsulant layer 310 is applied on the surfaces of the dice 304, and after the eneapsulant layer 310 is cured, phosphor 312 is dispersed without any mold restriction into the cavity delimited by the substrate 302 and the reflector 306, where the phosphor 312 flows freely until a surface balance is achieved. As a result of this process, the phosphor layer 312 is normally convex. The thickness of the encapsulant layer 310 controls the distance between the plurality of dice surfaces and the phosphor layer, thus reducing the light absorption and increasing the light extraction since only a small part of the light scattered from the remote phosphor layer 312 reaches the plurality of dice 304. Increased distance also improves color uniformity due to averaging of the light leaving the die, or the plurality of dice 304 surfaces.

The remote phosphor approach described in reference to FIG. 3a, has several technological limitations. A layer of phosphor deposited on the encapsulant layer becomes thermally insulated from the substrate and an optional heat sink, to which the substrate is thermally attached. This makes thermal management of the assembly difficult.

To mitigate the thermal management issues, an alternative conceptual cross-section of an exemplary light-emitting device 300 with remote phosphor location is depicted in FIG. 3b. A plate 314 made of transparent, thermally conductive material, e.g., sapphire, is disposed on the reflector 306. A layer of phosphor 316 is then deposited on the top of the plate 314. The transparent plate 314, the reflector 306, and the substrate 302 should be attached to one another and to an optional heat sink (not shown in FIG. 3b) using any thermally conductive means (not shown in FIG. 3b) to maximize heat transfer between these components. By means of an example, such a thermally conductive means may comprise any thermally conductive adhesive or solder material, such as metal filled epoxy, eutectic alloy solder, and any other thermally conductive means known to a person skilled in the art. Such a configuration allows heat to flow through the plate 314 and the reflector 306 to the substrate 302, and the optional heat sink.

Although the configuration disclosed in reference to FIG. 3b and associated text mitigates the thermal management issue, the disadvantage is a loss of light extraction efficiency due to an additional interface, refractive index mismatch, and lack of convexity of the plate 314/phosphor 316 assembly.

Accordingly, there is a need in the art for a light-emitting device providing solution to the above identified problems, as well as additional advantages evident to a person skilled in the art.

### SUMMARY

In one aspect of the disclosure, a light-emitting device with semi-remote phosphor layer location according to appended independent claims is disclosed. Preferred additional aspects are disclosed in the dependent claims.

### BRIEF DESCRIPTION OF THE DRAWINGS

The foregoing aspects described herein will become more readily apparent by reference to the following description when taken in conjunction with the accompanying drawings wherein:

FIG. 1 depicts a conceptual cross-section of an exemplary light-emitting device in accordance with known concepts;

FIG. 2 depicts a conceptual cross-section of another exemplary light-emitting device in accordance with known concepts;

FIG. 3 depicts a conceptual cross-section of yet another exemplary light-emitting device array in accordance with known concepts; and

FIG. 4 depicts a conceptual cross-section of an exemplary light-emitting device in accordance with an aspect of this disclosure.

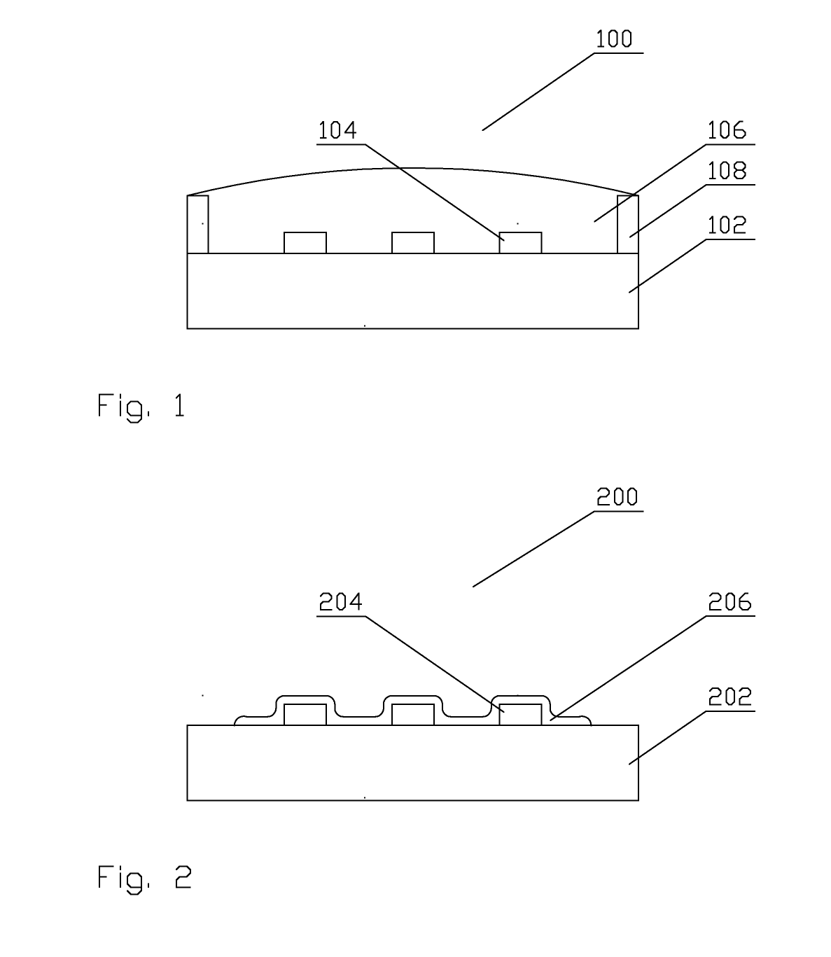

### DETAILED DESCRIPTION

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements disclosed as being on the “lower” side of other elements would then be oriented on the “upper” side of the other elements. The term “lower” can therefore encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various disclosed aspects may be illustrated with reference to one or more exemplary configurations. As used herein, the term “exemplary” means “serving as an example, instance, or illustration,” and should not necessarily be construed as preferred or advantageous over other configurations disclosed herein.

Furthermore, various descriptive terms used herein, such as “on” and “transparent,” should be given the broadest meaning possible within the context of the present disclosure. For example, when a layer is said to be “on” another layer, it should be understood that that one layer may be deposited, etched, attached, or otherwise prepared or fabricated directly or indirectly above or below that other layer. In addition, something that is described as being “transparent” should be understood as having a property allowing no significant obstruction or absorption of electromagnetic radiation in the particular wavelength (or wavelengths) of interest, unless a particular transmittance is provided.

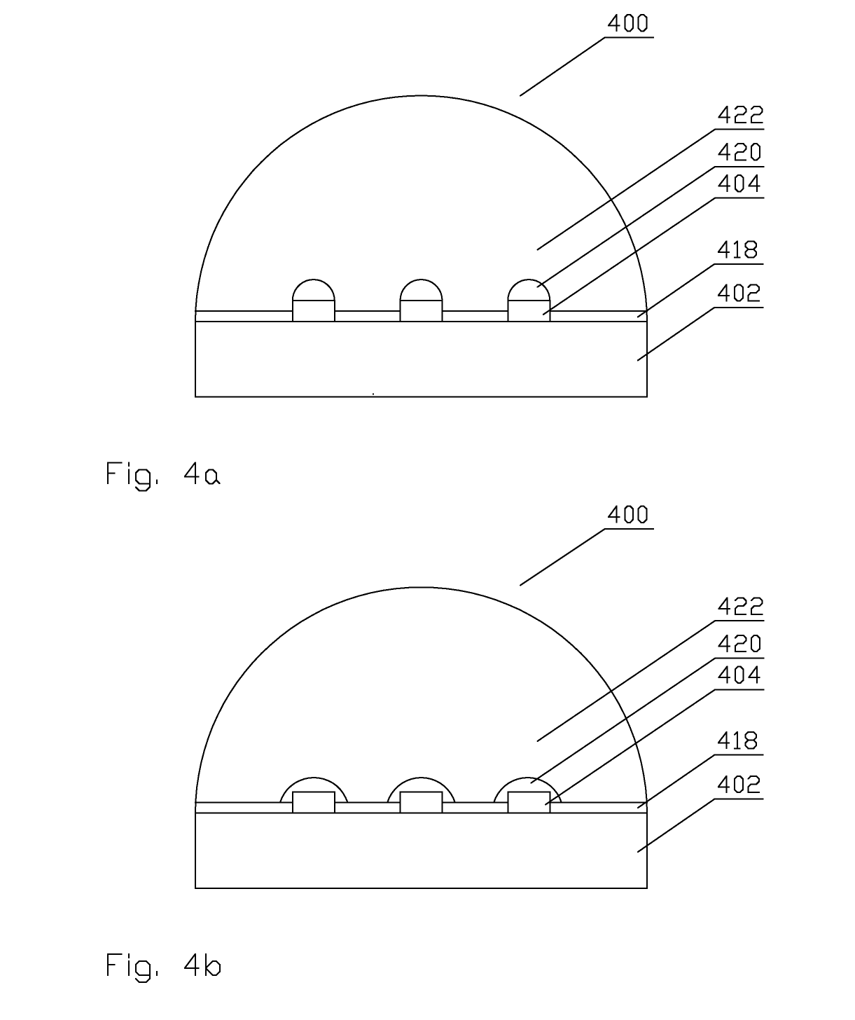

In accordance with one aspect, an exemplary light-emitting device comprises a complex lens. At least one semiconductor die is disposed on a substrate of the light-emitting device. The complex lens is created by forming one first lens comprising a clear transparent material directly on a surface of each one of at least one die, and by forming an outer lens comprising a clear transparent material filled uniformly with phosphor, directly encapsulating the substrate and the at least one die with the formed first lens. FIG. 4 depicts a conceptual cross-section of such an exemplary light-emitting device 400. A person skilled in the art will appreciate that although FIG. 4 depicts an exemplary light-emitting device comprising a plurality of dice 404, the concepts disclosed herein are equally applicable for an exemplary light-emitting device comprising a single die.

A substantially flat substrate 402 in addition to being a mechanical support is often used as a means for heat dissipation from the light-emitting device. A material is considered to be substantially flat if the irregularities in flatness would not cause light to be reflected by such irregularities. When used in the latter function the substrate 402 is made from a material with high thermal conductivity. Such material may comprise metals, e.g., Al, Cu, Si-based materials, or any other material whose thermal conductivity is appropriate for the light-emitting device in question. A person skilled in the art will appreciate that material appropriate for a light-emitting device with power dissipation of, e.g., 35 milliwatts (mW) is different than material appropriate for a light-emitting device with power dissipation of, e.g., 350 mW.

To improve light extraction from the light-emitting device 400, the surface of the substrate 402 exposed to the light emitted from the plurality of dice 404, i.e., the upper surface, may be treated, to acquire a specific reflectivity. In one aspect, such a treatment may comprise e.g., polishing, buffing, or any other process known to a person skilled in the art. In one aspect, such a treatment comprises polishing, buffing, or any other process known to a person skilled in the art.

In an alternative aspect, the desired reflectivity is achieved by applying a layer of reflective material 418 on the upper surface of the substrate 402. To maximize luminous efficiency, material with high reflectivity, e.g., noble metals like Pt, Au, Ag, or other materials, like Al, are used for this purpose. Reflective layers employing such materials possess predominantly specular reflectivity, unless specific technological process designed to increase diffusive reflectivity is followed.

In yet another aspect, further improvement in luminous efficiency as well as in spatial light distribution may be obtained by employing reflective surfaces possessing diffusive reflectivity. Consequently, in an alternative, the reflective layer 418 comprises a material with high diffusive reflectivity applied onto select region(s) of the upper surface of the substrate 402. As shown in FIG. 4, the selected regions exclude reserved regions, i.e., the areas of the substrate 402 on which the plurality of dice 404 is disposed in accordance with design goal for the light-emitting device 400. However, in an alternative aspect, the selected region may include the reserved regions. In accordance with one aspect, the reflective layer 418 comprises a titanium oxide or other oxide phases, in particular titanium dioxide.

Although most surfaces poses a mixture of diffuse and specular reflective properties, a person skilled in the art will appreciate that the terms specular and diffuse refer to predominant mode of reflection. Thus, as disclosed above, polished or buffed metallic objects and/or layers of metallic material posses specular reflectivity; matte surfaces posses diffuse reflectivity.

Further details regarding use of reflective surfaces possessing diffusive reflectivity is disclosed in a co-pending application Ser. No. ______, filed on XX/XX/XXXX, entitled REFLECTIVE SURFACE SUB-ASSEMBLY FOR A LIGHT-EMITTING DEVICE.

As depicted in FIG. 4a, a lens 420 of clear transparent material is formed on the upper surface of each of the plurality of dice 404. The term “clear” used herein means a transparent material excluding any coat or fill of phosphor(s); however, including optional doping material(s). Such an optional doping material may be employed to improve both optical and technological properties of the clear transparent material. Any material with optical properties, e.g., light transmission, refraction index, and technological properties, e.g., thermal stability, surface tension, viscosity and thixotropic properties satisfying design criteria for the light-emitting device 400, may be used as the clear transparent material. By means of an example, a clear silicone may be used. Any method know to a person skilled in the art can be used for forming the lens 420. By means of an example, a dispensing method may be used. In any case, care should be taken to prevent runaway of the clear transparent material from the upper surface onto the other exposed surfaces of the die 404. A person skilled in the art will appreciate that the term exposed surfaces excludes the bottom surface and those sections of the surfaces of the die 404 covered by the optional layer 418, as depicted in FIG. 4.

In an alternative aspect, an over-molding, using, e.g., a prefabricated stainless steel mold form may be used. In accordance with this aspect, exposed surfaces of the die 404 may be covered with the clear transparent material comprising the lens 420, as depicted in FIG. 4b.

Although the shape of the lens 420 depicted in FIG. 4 is hemispherical, any shape as determined with design criteria for the light-emitting device 400 and/or technological capabilities, is contemplated.

Once the plurality of lenses 420 are formed on the upper surface of each of the plurality of dice 404, clear transparent material is mixed with phosphor in a ratio determined by desired optical characteristics, e.g., correlated color temperature (CCT), color rendering index CRI, and other optical characteristics known to a person skilled in the art. It is further desirable that the refractive index of the clear transparent material to be mixed with phosphor should be the same or slightly smaller than the refractive index for the clear transparent material used for the plurality of lenses 420. An outer lens 422 comprising the mixture of the clear transparent material and phosphor is then formed directly encapsulating on a sub-assembly comprising the substrate 402 with the optional upper surface treatment, e.g., reflective layer 418, and the die or the plurality of dice 404 with formed plurality of lenses 420.

The shape of the formed outer lens 422 is determined with design criteria for the light-emitting device 400 and/or technological capabilities of the manufacturer. Accordingly, thermal management, desired distribution of the light emitted by the light-emitting device 400 may be considered as examples of such design criteria.

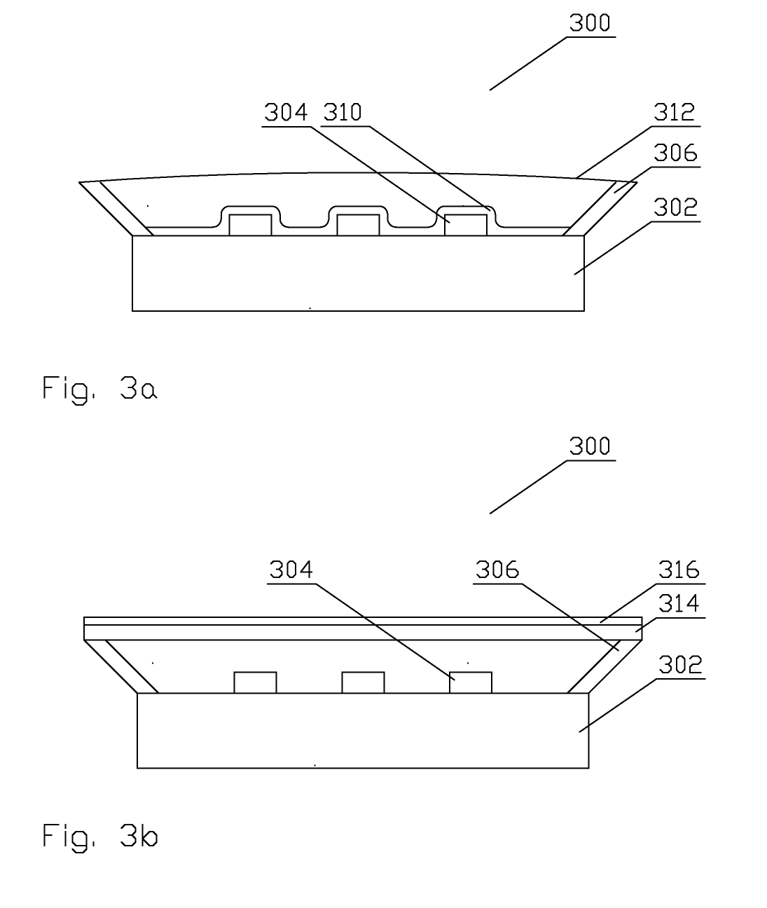

Regarding the thermal management, an outer lens 422 that has a high surface-to-volume ratio, which, together with the mixture of the clear transparent material and phosphor comprising the outer lens 422 being in contact with the substrate 402 provides thermal management, comparable with the remote phosphor placement on the thermally conductive flat plate like sapphire, as described above in reference to FIG. 3b and associated text. As depicted in FIG. 4, the outer lens 422 is in contact with the substrate 402 either through the intervening reflective layer 418 or, in case that the desired reflectivity is achieved by other means than reflective layer 418, e.g., by polishing the upper surface of the substrate 402, directly (not shown).

Regarding the desired distribution of the light, several consideration affect the design of the outer lens 422, e.g., distribution of the light emitted by the individual die or dices 404, shape of the lens(es) 420, scattering effect in the material of the lens 422, shape of the desired illuminated plane, and the like. Consequently, different shapes of the outer lens 422, from simple concave, convex, i.e., hemispherical lens to sophisticated free-formed lens may be required.

The various aspects of this disclosure are provided to enable one of ordinary skill in the art to practice the present invention. Modifications to various aspects of a presented throughout this disclosure will be readily apparent to those skilled in the art, and the concepts disclosed herein may be extended to other applications. Thus, the claims are not intended to be limited to the various aspects of the reflective surfaces for a light-emitting device array presented throughout this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A light-emitting device, comprising:
a sub-assembly, comprising
a substrate;
at least one semiconductor die disposed on the substrate; and
a first lens, comprising clear transparent material, formed directly on each of the at least one semiconductor die; and
a second lens comprising a phosphor filled transparent material disposed directly on the sub-assembly.

2. The apparatus according to claim 1, wherein the first lens is formed directly on the upper surface of each of the at least one semiconductor die.

3. The apparatus according to claim 1, wherein the first lens is formed directly on the exposed surfaces of each of the at least one semiconductor die.

4. The apparatus according to claim 1, wherein the first lens formed directly on each of the at least one semiconductor die is hemispherical shape.

5. The apparatus according to claim 1 wherein the second lens is hemispherical shape.

6. The apparatus according to claim 1, wherein the upper face of the substrate is treated by polishing and/or buffing to acquire specific reflectivity.

7. The apparatus according to claim 6, further comprising:
a specular reflective layer applied on selected regions on the substrate; and
wherein the at least one semiconductor die is disposed on reserved regions on the substrate.

8. The apparatus according to claim 1, further comprising:
a diffusive reflective layer applied on selected regions on the substrate; and
wherein the at least one semiconductor die is disposed on reserved regions on the substrate.

9. The apparatus according to claim 8, wherein the diffusive reflective layer comprises titanium oxide.

10. The apparatus according to claim 8, wherein the diffusive reflective layer comprises oxide phases or compositions of titanium.

11. A method for producing a light-emitting device, the method comprising:
disposing at least one semiconductor die on a substrate;
forming a first lens comprising clear transparent material directly on each of the at least one semiconductor die; and
forming a second lens comprising a phosphor filled transparent material directly encapsulating the substrate and the at least one semiconductor die with the formed first lens.

12. The method according to claim 11, wherein the forming a first lens comprises:
forming a first lens directly on the upper surface of each of the at least one semiconductor die.

13. The method according to claim 11, wherein the forming a first lens comprises:
forming a first lens directly on the exposed surfaces of each of the at least one semiconductor die.

14. The method according to claim 11, wherein the first lens formed directly on each of the at least one semiconductor die is hemispherical shape.

15. The method according to claim 11 wherein the second lens is hemispherical shape.

16. The method according to claim 11, further comprising:
treating the upper face of the substrate by polishing and/or buffing to acquire specific reflectivity.

17. The method according to claim 11, further comprising:
applying a specular reflective layer on selected regions on the substrate; and
wherein the at least one semiconductor die is disposed on reserved regions on the substrate.

18. The method according to claim 11, further comprising:
applying a diffusive reflective layer on selected regions on the substrate; and
wherein the at least one semiconductor die is disposed on reserved regions on the substrate.

19. The method according to claim 18, wherein the diffusive reflective layer comprises titanium oxide.

20. The method according to claim 18, wherein the diffusive reflective layer comprises oxide phases or compositions of titanium.
